(19) United States
(12) Patent Application Publication
(10) Pub. No.: US 2012/0018888 A1
(43) Pub. Date: Jan. 26, 2012

(54) SEMICONDUCTOR DEVICES AND METHOD OF FORMING THE SAME

(75) Inventor: Min Sung KO, Pyeongtaek-si (KR)

(73) Assignee: HYNIX SEMICONDUCTOR INC., Icheon-si (KR)

(21) Appl. No.: 13/179,879

(22) Filed: Jul. 11, 2011

(30) Foreign Application Priority Data
Jul. 23, 2010 (KR) 10-2010-0071423

(51) Int. Cl. H01L 29/49; H01L 21/762

(52) U.S. Cl. 257/751; 438/424; 257/E21.546; 257/E29.155

(57) ABSTRACT

A method of forming semiconductor devices includes stacking an insulating layer and a polysilicon layer over a semiconductor substrate, forming a region where nitrogen (N) is scattered in a place adjacent to a surface of the polysilicon layer within the polysilicon layer using a plasma method, and depositing a doped polysilicon layer on the polysilicon layer including the region where nitrogen (N) is scattered.

### CROSS-REFERENCE TO RELATED APPLICATION

Priority to Korean patent application number 10-2010-0071423 filed on Jul. 23, 2010, the entire disclosure of which is incorporated by reference herein, is claimed.

### BACKGROUND

Exemplary embodiments relate to semiconductor devices and a method of forming the same and, more particularly, to semiconductor devices and a method of forming the same, which may reduce/minimize impurities accumulated on an insulating layer under a polysilicon layer even though a concentration of the impurities included in the polysilicon layer increases.

In general, a polysilicon layer may be used as a gate pattern of a semiconductor device. For example, in a NAND flash memory device, floating gates into which electrons are injected or from which electrons are discharged may be formed using the polysilicon layer. Gate patterns, such as the floating gates, are formed over a gate insulating layer formed on a semiconductor substrate. Furthermore, impurities are implanted into the polysilicon layer used as the gate patterns in order to implement a gate pattern having a low resistance value.

Meanwhile, the area of the gate pattern decreases as the size of the semiconductor device decreases. The amount of impurities included in a polysilicon layer may become relatively insufficient, and thus a poly depletion may occur. In order to reduce the poly depletion, a concentration of the impurities within the polysilicon layer may increase by further implanting impurities into the polysilicon layer. In this case, however, the impurities of a high concentration implanted into the polysilicon layer may diffuse and thus accumulated on an insulating layer under the polysilicon layer. Consequently, reliability of semiconductor devices may deteriorate.

### BRIEF SUMMARY

Exemplary embodiments relate to semiconductor devices and a method of forming the same, which are capable of solving a problem in which impurities are accumulated on an insulating layer under a polysilicon layer even though a concentration of the impurities within the polysilicon layer is increased.

A method of forming semiconductor devices according to an aspect of the present disclosure includes stacking an insulating layer and a polysilicon layer over a semiconductor substrate, forming a region where nitrogen (N) is scattered in a place adjacent to a surface of the polysilicon layer within the polysilicon layer using a plasma method, and depositing a doped polysilicon layer on the polysilicon layer including the region where nitrogen (N) is scattered.

The region where nitrogen (N) is scattered is formed to prevent impurities within the doped polysilicon layer from diffusing toward the insulating layer and to prevent a nitride layer from being formed in the polysilicon layer. Forming the region where nitrogen (N) is scattered preferably is performed in 3 to 10 seconds.

After forming the doped polysilicon layer, the method further includes removing portions of the doped polysilicon layer, the polysilicon layer, and the insulating layer to expose the semiconductor substrate, forming trenches by etching the exposed semiconductor substrate, and forming isolation layers in the respective trenches.

After forming the isolation layers, the impurities may be additionally implanted into the doped polysilicon layer.

After additionally implanting the impurities, a rapid thermal process (RTP) may be further performed in order to diffuse and activate the impurities within the doped polysilicon layer.

The doped polysilicon layer may be deposited using an impurity gas and a silicon source gas.

A semiconductor device according to another aspect of the present disclosure includes an insulating layer formed on a semiconductor substrate, a polysilicon layer formed on the insulating layer, a nitrogen (N) scattering region formed in a place adjacent to a surface of the polysilicon layer within the polysilicon layer, and a doped polysilicon layer formed on the polysilicon layer including the nitrogen (N) scattering region.

The nitrogen (N) preferably is discontinuously scattered in an ion state and an atomic state within the nitrogen (N) scattering region.

The grain of the polysilicon layer preferably is smaller than the grain of the doped polysilicon layer.

3-valence or 5-valence impurity atoms are within the doped polysilicon layer.

The polysilicon layer and the doped polysilicon layer may be used as the floating gates of a NAND flash memory device.

Impurities, having a lower concentration than impurities within the doped polysilicon layer, preferably are within the polysilicon layer.

A concentration of the nitrogen(N) within the region, where nitrogen(N) is scattered, increases with the approach of surface of the polysilicon layer.

### BRIEF DESCRIPTION OF THE DRAWINGS

FIGS. 1A to 1D are cross-sectional views illustrating a method of forming semiconductor devices according to an exemplary embodiment of this disclosure; and

FIGS. 2A to 2C are cross-sectional views illustrating a method of forming semiconductor devices according to another exemplary embodiment of this disclosure.

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

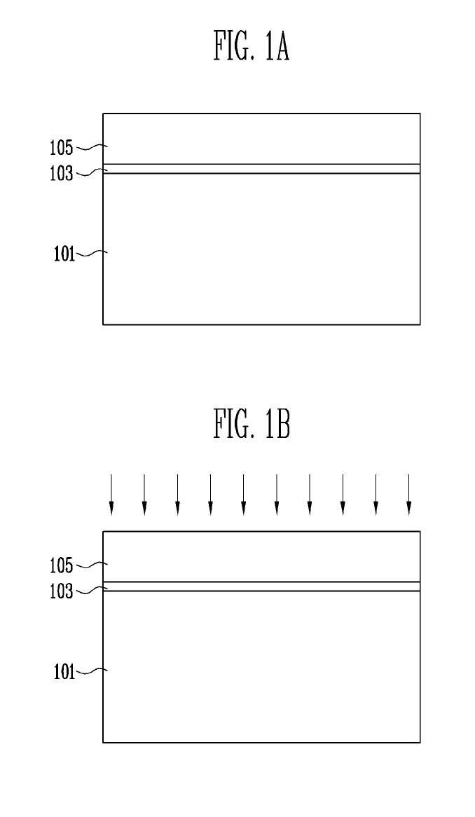

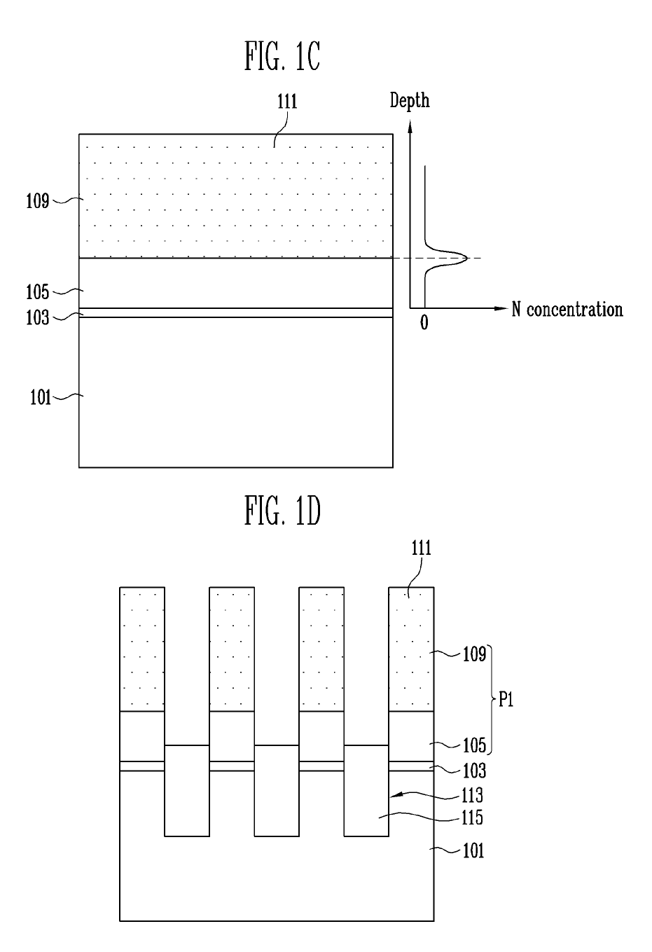

FIGS. 1A to 1D are cross-sectional views illustrating a method of forming semiconductor devices according to an exemplary embodiment of this disclosure. In particular, FIGS. 1A to 1D are cross-sectional views illustrating a method of forming floating gates of a semiconductor memory device.

Referring to FIG. 1A, an insulating layer 103 and a polysilicon layer 105 are formed over a semiconductor substrate 101 including isolation regions and active regions.

The insulating layer 103 is formed to insulate gate patterns such as floating gates. In particular, the insulating layer 103 is used as a tunnel dielectric layer through which electrons pass for charging or discharging the floating gates with the electrons, e.g., the insulating layer 103 is used as the tunnel dielectric layer through which a tunnel injection for writing operation and tunnel release for erasing operation occur. The insulating layer 103 may be formed by depositing an oxide layer or may be formed by oxidizing the semiconductor substrate 101. The insulating layer 103 may be formed of a silicon oxide (SiO₂) layer.

The polysilicon layer 105 is a conductive layer used for gate patterns such as floating gates. According to an example, the polysilicon layer 105 is formed on the insulating layer 103, and includes a first nano-scale grain. Here, the size of the first nano-scale grain is smaller than a second nano-scale grain of a doped polysilicon layer to be subsequently formed. This is for making uniform the boundary of the first nano-scale grain of the polysilicon layer 105 per unit area so that the memory cells of the semiconductor device have a uniform characteristic after the polysilicon layer 105 is patterned.

Furthermore, impurities within the polysilicon layer 105 have a lower concentration than the impurities of the doped polysilicon layer to be subsequently formed. Since the impurities are within the polysilicon layer 105, the polysilicon layer 105 can have electrical conductivity, and thus the polysilicon layer 105 can be used as the floating gates.

Furthermore, a concentration of the impurities within the polysilicon layer 105 is low to the extent that a characteristic of the insulating layer 103 is not degraded because the impurities diffuse toward the insulating layer 103. The polysilicon layer 105 including the impurities of a low concentration may reduce a probability of an occurrence of the phenomenon in which the impurities of the doped polysilicon layer diffuse into the insulating layer 105.

Referring to FIG. 1B, a region where nitrogen (N) is scattered is formed in a place adjacent to a surface of the polysilicon layer 105 within the polysilicon layer 105 through a plasma method. A concentration of the nitrogen(N) within the region, where nitrogen(N) is scattered, increases with the approach of surface of the polysilicon layer 105. The process of forming the region where nitrogen (N) is scattered using the plasma method is performed, for example, for 10 seconds or less in order to prevent a nitride layer from being formed in the polysilicon layer 105. If the nitride layer is formed in the polysilicon layer 105, the polysilicon layer 105 and the doped polysilicon layer to be subsequently formed may not be used as the floating gates.

Furthermore, if the nitride layer is formed, an etch process is not smoothly performed when patterns are formed by etching the polysilicon layer 105 and the doped polysilicon layer to be subsequently formed, thereby failing in forming the patterns of a desired profile. For this reason, the process of forming the region where nitrogen (N) is scattered using the plasma method may be performed for 10 seconds or less in order to prevent the nitride layer from being formed.

Also, the process of forming the region where nitrogen (N) is scattered using the plasma method may be performed for 3 seconds or more in order to minimize the degradation of a cell characteristic due to the contamination of nitrogen (N) and to reduce a probability that the impurities of the doped polysilicon layer to be subsequently formed diffuse into the polysilicon layer 105.

If the region where nitrogen (N) is scattered is formed using the plasma method performed for 3 to 10 seconds, nitrogen (N) is scattered in an ion state, thus forming SiNx, or diffusing in an atomic state without being combined with silicon (Si). SiNx and nitrogen (N) of the atomic state are not formed in a consecutive state and formed without having a specific physical thickness.

Referring to FIG. 1C, the doped polysilicon layer 109 including impurities 111 is formed over the polysilicon layer 105 including the region where nitrogen (N) is scattered. The doped polysilicon layer 109, together with the polysilicon layer 105, is a conductive layer used as gate patterns, such as floating gates. According to an example, the doped polysilicon layer 109 has the second nano-scale grain of which the size is greater than the first nano-scale grain.

The impurities 111 within the doped polysilicon layer 109 may include 5-valence atoms, such as phosphorus (P), or 3-valence atoms, such as boron (B).

The doped polysilicon layer 109 may be formed by depositing a doped silicon layer using an impurity gas and a silicon source gas. In the process of depositing the doped polysilicon layer, SiH₄ or SiH₂Cl₂ gas may be used as the silicon source gas. Furthermore, the impurity gas may vary according to a type of the impurities 111 to be doped into the doped polysilicon layer 109. For example, when the impurities 111 are phosphorus (P), PH₃ gas may be used as the impurity gas.

In the exemplary embodiment of this disclosure, a region where nitrogen (N) is scattered may be formed within the polysilicon layer 105 adjacent to the doped polysilicon layer 109 through the plasma method performed before the doped polysilicon layer 109 is formed.

The region including nitrogen (N) of a high concentration may reduce a probability that the impurities 111 within the doped polysilicon layer 109 diffuse into the bottom of the polysilicon layer 105 under the region where nitrogen (N) is scattered and thus being accumulated on the insulating layer 103. Furthermore, the region including nitrogen (N) of a high concentration may reduce the amount of the diffusion of the impurities 111, and thus minimizing a change of a cell characteristic, as compared with a case where a nitride layer or an oxide layer is formed at the interface of the doped polysilicon layer 109 and the polysilicon layer 105 and the case where an N₂O annealing process or an NH₃ nitrification process is performed.

Meanwhile, the polysilicon layer 105 includes impurities 111 before the region where nitrogen (N) is scattered is formed. Accordingly, although the amount of the impurities 111 diffusing into the bottom of the polysilicon layer 105 from the doped polysilicon layer 109 decreases due to the region where nitrogen (N) is scattered, the polysilicon layer 105 can be used as the floating gates.

Referring to FIG. 1D, the doped polysilicon layer 109 and the polysilicon layer 105 are patterned, and isolation layers 115 are formed in the isolation regions of the semiconductor substrate 101.

More particularly, portions of the polysilicon layer 109 and the polysilicon layer 105 in the isolation regions of the semiconductor substrate 101 are removed to expose the insulating layer 103. Accordingly, conductive patterns P1 to be used as gate patterns, such as floating gates, are formed in the active regions of the semiconductor substrate 101.

The exposed insulating layer 103 is etched to expose the isolation regions of the semiconductor substrate 101, and the isolation regions of the exposed semiconductor substrate 101 are etched to form trenches 113 in the semiconductor substrate 101. The conductive patterns P1 and the trenches 113 may be formed by etching the doped polysilicon layer 109, the polysilicon layer 105, the insulating layer 103, and the semiconductor substrate 101 using a hard mask pattern (not shown) as an etch mask.

After the trenches 113 are formed, an insulating layer is formed by filling the trenches 113. Here, the insulating layer may be formed on the active regions of the semiconductor substrate 101, e.g., on the top surface the hard mask pattern over the doped polysilicon layer 109. In order to remove the insulating layer of the active regions of the semiconductor substrate 101, such as a chemical mechanical polishing (CMP) process, may be performed. For example, the polishing process of the insulating layer may be performed until the top of the hard mask pattern is exposed so that the insulating layer is removed from the active regions of the semiconductor substrate 101.

Next, isolation layers 115 are formed by controlling the height of the insulating layer through an etch process. According to an example, the top of the isolation layers 115 is lower than the top of the doped polysilicon layer 109, but higher than the top of the insulating layer 103. This is for improving the coupling ratio the floating gates and control gates to be formed in a subsequent process.

After the isolation layers 115 are formed, the remaining hard mask pattern may be removed.

As described above, in the exemplary embodiment of this disclosure, the region where nitrogen (N) is scattered is formed within the polysilicon layer 105 adjacent to a surface of the polysilicon layer 105 through the plasma method. Accordingly, a probability that the impurities 111 diffuse into the insulating layer 103 may decrease.

In the exemplary embodiment of this disclosure, although the number of impurity atoms within the doped polysilicon layer 109 increases from 3.0 to 4.0E20 atoms to 3.0 to 7.5E20 atoms or higher, a probability that the impurities 111 are accumulated on the insulating layer 103 may decrease.

Furthermore, in the exemplary embodiment of this disclosure, a probability of occurrence of the poly depletion phenomenon may decrease because the impurities 111 of the doped polysilicon layer 109 may be controlled to have a desired concentration.

In addition, in the exemplary embodiment of this disclosure, the doped polysilicon layer 109 is formed by depositing a doped silicon layer using an impurity gas and a silicon source gas. The impurity gas has a certain amount of the impurities 111 so that a concentration of the impurities 111 within the doped polysilicon layer 109 has a target concentration. Accordingly, an additional ion implantation process may not be performed in a subsequent process.

If the ion implantation process is not performed, the following effects may be expected.

First, a deformation of a pattern profile due to the loss of the polysilicon layer may decrease because the polysilicon layer can be prevented from becoming amorphous and being lost owing to the influence of ion implantation. Second, the time taken to manufacture semiconductor devices may decrease because a rapid thermal process (RTP) that is performed in order to diffuse impurities after an ion implantation process may be omitted. Third, a probability that ions are implanted at a depth deeper than a target depth through the space between lattices within silicon (Si) may decrease. Fourth, the impurities 111 need not to be further implanted after the conductive patterns P1 are formed. In this case, a deformation of a profile of the conductive patterns P1, such as an inclination of the conductive patterns P1, owing to ion implantation energy may decrease.

After the conductive patterns P1 are formed, known processes are performed. For example, a dielectric layer may be formed by stacking an oxide layer, a nitride layer and an oxide layer on a surface of the conductive patterns P1 and the isolation layers 115, and a conductive layer for a control gate may be formed over the dielectric layer. The stack type gate patterns of the semiconductor memory device are formed by patterning the conductive layer for the control gate, the dielectric layer, and the conductive patterns P1. The junctions of the semiconductor memory device are formed by implanting impurities into the semiconductor substrate 101 on both sides of each of the gate patterns using the stack type gate patterns as a mask. An annealing process for diffusing and activating the impurities formed in the junctions is performed.

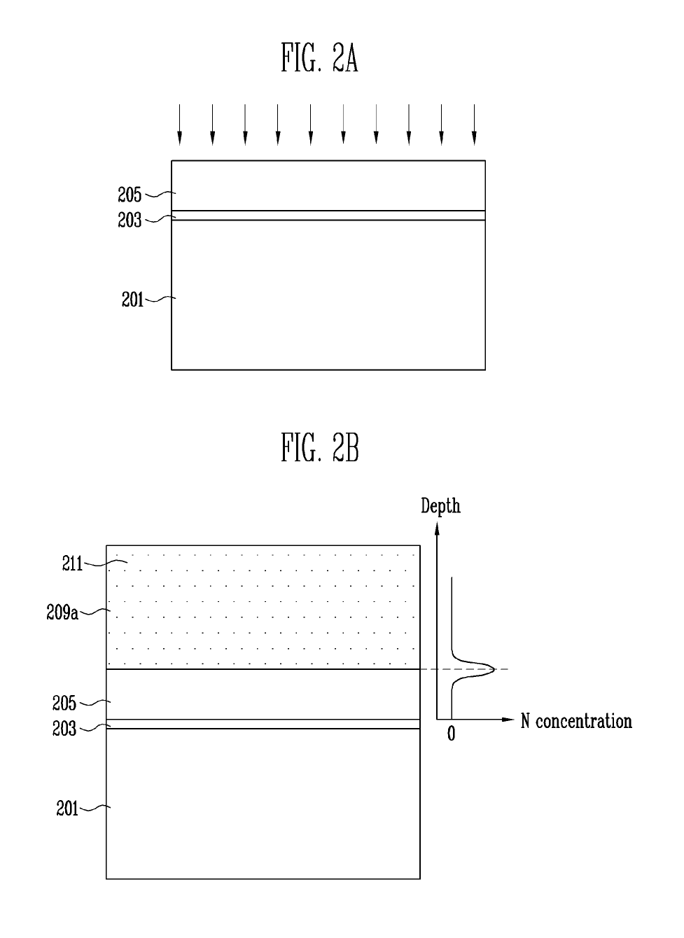

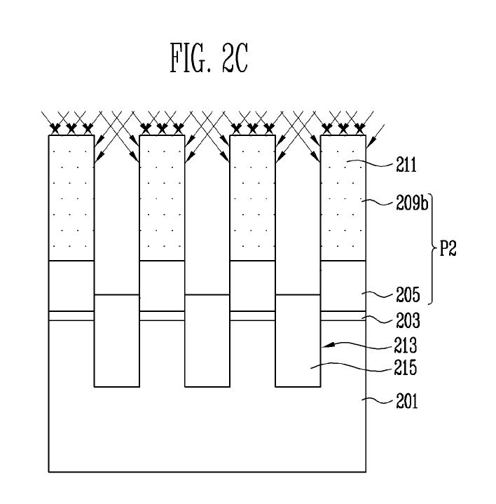

FIGS. 2A to 2C are cross-sectional views illustrating a method of forming semiconductor devices according to another exemplary embodiment of this disclosure. In particular, FIGS. 2A to 2C are cross-sectional views illustrating a method of forming floating gates of a semiconductor memory device.

Referring to FIG. 2A, an insulating layer 203 and a polysilicon layer 205 are formed over a semiconductor substrate 201, including isolation regions and active regions.

The insulating layer 203 and the polysilicon layer 205 may be used as the same purposes as in the above mentioned exemplary embodiment and may be formed using the same method as that described in the above mentioned exemplary embodiment. Furthermore, the polysilicon layer 205 may have a first nano-scale grain smaller than the second nano-scale grain of a doped polysilicon layer to be subsequently formed in order to make uniform an each cell characteristic of the semiconductor device, as described in the above mentioned exemplary embodiment.

Referring to FIG. 2B, a region where nitrogen (N) is scattered is formed in a place adjacent to a surface of the polysilicon layer 205 within the polysilicon layer 205 through a plasma method. A concentration of the nitrogen(N) within the region, where nitrogen(N) is scattered, increases with the approach of surface of the polysilicon layer 205. Here, the process of forming the region where nitrogen (N) is scattered using the plasma method may be performed for 3 to 10 seconds because of the same reasons as those described in the above mentioned exemplary embodiment.

The doped polysilicon layer 209a including impurities 211 is formed over the polysilicon layer 207, including the region where nitrogen (N) is scattered, as described in the above mentioned exemplary embodiment. Here, the impurities 211 within the doped polysilicon layer 209a may have a first concentration. For example, the number of atoms of the impurities 211 within the doped polysilicon layer 209a may be 3.0 to 4.0E20 atoms. Both the doped polysilicon layer 209a and the polysilicon layer 205 are conductive layers used as gate patterns, such as floating gates. Furthermore, the doped polysilicon layer 209a may have the second nano-scale grain greater than the first nano-scale grain.

Referring to FIG. 2C, the doped polysilicon layer 209a and the polysilicon layer 205 are patterned, and isolation layers 215 are formed in the isolation regions of the semiconductor substrate 201. More particularly, part of the doped polysilicon layer and part of the polysilicon layer 205 in the isolation regions of the semiconductor substrate 201 are removed to expose the insulating layer 203 formed. Accordingly, conductive patterns P2 to be used as gate patterns, such as floating gates, are formed in the active regions of the semiconductor substrate 201.

The exposed insulating layer 203 is etched to expose the semiconductor substrate 201. The exposed semiconductor substrate 201 is etched to form trenches 213 in the isolation regions of the semiconductor substrate 201. The conductive patterns P2 and the trenches 213 may be formed as described in the above mentioned exemplary embodiment. Furthermore, the isolation layers 215 may be formed as described in the above mentioned exemplary embodiment.

In the another exemplary embodiment, however, after the conductive patterns P2 and the isolation layers 215 are formed, the impurities 211 are implemented by targeting the conductive patterns P2 in order for the gate patterns to have a low resistance value. Here, the impurities 211 may be implanted into only the doped polysilicon layer. If the impurities 211 are further implemented into the doped polysilicon layer as described above, a doped polysilicon layer 209b, including the impurities 211 and having a second concentration higher than the first concentration, may be formed. For example, the number of atoms of the impurities 211 within the doped polysilicon layer 209b may be 3.0 to 7.5E20 atoms.

Accordingly, each of the conductive patterns P2 has a structure in which the polysilicon layer 205 and the doped polysilicon layer 209b are stacked.

The impurities 211 may include 5-valence atoms, such as phosphorus (P), or 3-valence atoms, such as boron (B).

The impurities 211 may be implanted into the conductive patterns P2 using an ion implantation method or a plasma ion doping method. In the ion implantation method, ionized impurities are implanted into a target by accelerating the ionized impurities using specific energy. In the plasma ion doping method, atoms are doped by ionizing the atoms in a plasma state.

The impurities 211 further implanted may be diffused or activated by a rapid thermal process (RTP) or heat generated in a subsequent process.

After the conductive patterns P2 including the impurities 211 are formed, known processes are performed as in the first exemplary embodiment.

As described above, in the another exemplary embodiment of this disclosure, the region where nitrogen (N) is scattered is formed within the polysilicon layer 205 under the doped polysilicon layer 209b, before the doped polysilicon layer 209b is formed, by using the plasma method. Accordingly, a probability that the impurities 211 within the doped polysilicon layer 209b diffuse into the insulating layer 203 may decrease. Consequently, although the number of atoms of the impurities 211 increases from 3.0 to 4.0E20 atoms to 3.0 to 7.5E20 atoms or higher, a probability that the impurities are accumulated on the insulating layer 203 may decrease. Furthermore, a probability of occurrence of the poly depletion phenomenon may decrease because impurities 211 within the doped polysilicon layer 209b may be controlled to have a desired concentration.

According to this exemplary embodiment of this disclosure, as described above, the region where nitrogen (N) is scattered is formed in a place adjacent to a surface of the polysilicon layer within the polysilicon layer using the plasma method. Next, the doped polysilicon layer having the impurities of a high concentration is formed over the polysilicon layer including the region where nitrogen (N) is scattered. The region where nitrogen (N) is scattered may reduce a diffusion of the impurities within the doped polysilicon layer from into the insulating layer under the polysilicon layer.

Accordingly, although the amount of the impurities included within the doped polysilicon layer increases, a probability that the impurities are accumulated on the insulating layer under the polysilicon layer may decrease.

What is claimed is:

1. A method of forming semiconductor devices, comprising:
stacking an insulating layer and a polysilicon layer over a semiconductor substrate;
forming a region where nitrogen (N) is scattered in a place adjacent to a surface of the polysilicon layer within the polysilicon layer; and
depositing a doped polysilicon layer on the polysilicon layer including the region where nitrogen (N) is scattered.

2. The method of claim 1, wherein the region where nitrogen(N) is scattered is formed to prevent a nitride layer from being formed in the polysilicon layer.

3. The method of claim 1, wherein the forming of the region where nitrogen (N) is scattered is performed using a plasma method.

4. The method of claim 2, wherein the plasma method is performed for 3 to 10 seconds.

5. The method of claim 1, further comprising:
after forming the doped polysilicon layer,
removing portions of the doped polysilicon layer, the polysilicon layer, and the insulating layer to expose the semiconductor substrate;
forming trenches by etching the exposed semiconductor substrate; and
forming isolation layers in the respective trenches.

6. The method of claim 4, further comprising additionally implanting impurities into the doped polysilicon layer, after forming the isolation layers.

7. The method of claim 5, further comprising performing a rapid thermal process (RTP) for diffusing and activating the impurities within the doped polysilicon layer, after additionally implanting the impurities.

8. The method of claim 1, wherein the doped polysilicon layer is deposited using an impurity gas and a silicon source gas.

9. The method of claim 1, wherein a grain of the polysilicon layer is smaller than a grain of the doped polysilicon layer.

10. The method of claim 1, wherein 3-valence or 5-valence impurity atoms are included within the doped polysilicon layer.

11. The method of claim 1, wherein the polysilicon layer and the doped polysilicon layer are used as floating gates of a NAND flash memory device.

12. The method of claim 1, wherein a concentration of the nitrogen(N) increases with the approach of surface of the polysilicon layer.

13. The method of claim 1, wherein impurities, having a lower concentration than impurities within the doped polysilicon layer, are included within the polysilicon layer.

14. A semiconductor device, comprising:
an insulating layer formed on a semiconductor substrate;
a polysilicon layer formed on the insulating layer;
a nitrogen (N) scattering region formed in a place adjacent to a surface of the polysilicon layer within the polysilicon layer; and
a doped polysilicon layer formed on the polysilicon layer including the nitrogen (N) scattering region.

15. The semiconductor device of claim 14, wherein the nitrogen (N) is discontinuously scattered in an ion state and an atomic state within the nitrogen (N) scattering region.

16. The semiconductor device of claim 14, wherein a grain of the polysilicon layer is smaller than a grain of the doped polysilicon layer.

17. The semiconductor device of claim 14, wherein 3-valence or 5-valence impurity atoms are included within the doped polysilicon layer.

18. The semiconductor device of claim 14, wherein the polysilicon layer and the doped polysilicon layer are used as floating gates of a NAND flash memory device.

19. The semiconductor device of claim 14, wherein impurities, having a lower concentration than impurities within the doped polysilicon layer, are included within the polysilicon layer.

20. The semiconductor device of claim 14, wherein a concentration of the nitrogen(N) within the nitrogen(N) scattering region increases with the approach of surface of the polysilicon layer.
